(19) United States
(12) Patent Application Publication
(10) Pub. No.: US 2012/0331501 A1
(43) Pub. Date: Dec. 27, 2012

(54) LOW-PASS FILTER CIRCUIT

(75) Inventor: Steven Shafer, Chittenango, NY (US)

(73) Assignee: JOHN MEZZALINGUA ASSOCIATES, INC., East Syracuse, NY (US)

(21) Appl. No.: 13/167,497

(22) Filed: Jun. 23, 2011

(51) Int. Cl. H04N 7/16; H03H 7/01

(52) U.S. Cl. 725/27; 333/176; 348/E05.096

(57) ABSTRACT

This disclosure relates generally to community access or cable television (CATV) signals and to in-home entertainment signals sharing a CATV distribution network. A low-pass filter is disclosed which can be used to restrict in-home entertainment signals that are using the CATV distribution network from leaving a subscriber premise network. The low-pass filter is placed at an entry port of a CATV subscriber premise network. The low-pass filter allows both upstream and downstream CATV signal frequency bands to enter and exit the subscriber premise network. The low-pass filter blocks signals in the in-home entertainment frequency band from exiting the subscriber premise network. The low-pass filter includes at least one LC resonant circuit element, and at least one mechanical resonant circuit element. The low-pass filter is sized small enough that it can fit in existing CATV equipment.

### BACKGROUND OF THE INVENTION

1. Technical Field

This disclosure relates generally to community access or cable television (CATV) signals and to in-home entertainment signals sharing a CATV distribution network. More particularly, the present disclosure relates to a low-pass filter for blocking in-home entertainment signals that are using the CATV distribution network from leaving a subscriber premises network.

2. State of the Art

CATV networks use an infrastructure of interconnected coaxial cables, splitters, amplifiers, filters, trunk lines, cable taps, drop lines and other signal-conducting devices to supply and distribute high frequency “downstream” signals from a main signal distribution facility, known as a head-end, toward subscriber premises such as homes and businesses. The downstream signals operate the subscriber equipment, such as television sets, telephones, and computers. The typical CATV network is a two-way communication system. CATV networks also transmit “upstream” signals from the subscriber equipment back to the head-end of the CATV network. For example, upstream bandwidth may include data related to video on demand services, such as video requests and billing authorization. Two-way communication is also utilized when using a personal computer connected through the CATV infrastructure to the public Internet, for example, when sharing photo albums or entering user account information. In yet another example, voice over Internet protocol (VOIP) telephones and security monitoring equipment use the CATV infrastructure and the public Internet as the communication medium for transmitting two-way telephone conversations and monitoring functions.

To permit simultaneous communication of upstream and downstream CATV signals and the interoperability of the subscriber equipment and the equipment associated with the CATV network infrastructure outside of a subscriber premises, the downstream and upstream signals are confined to two different frequency bands. In most CATV networks the downstream frequency band, or downstream bandwidth, is within the range of 54-1002 megahertz (MHz) and the upstream frequency band, or upstream bandwidth, is within the range of 5-42 MHz.

An in-home entertainment network may be coupled to the CATV network via the same coaxial cable delivering the downstream and upstream bandwidth of the CATV system. The in-home entertainment network can be a network providing multiple streams of high definition video and gaming entertainment. Examples of in-home entertainment network technologies include Ethernet, HomePlug, Home Phoneline Networking Alliance (HPNA), 802.11n, and the Multimedia over Coax Alliance (MoCA) standard network protocol. These in-home entertainment networks used the CATV coaxial cable network system for transmitting signals, utilizing a frequency band above the 1002 MHz maximum frequency of the CATV network signals. It is undesirable for the in-home entertainment signals generated within a particular subscriber premises network to exit the subscriber premise network and travel to either another subscriber premise network or the CATV head-end facility. Thus it is desirable to have an electronic filter circuit that will block in-home entertainment network signals from leaving a subscriber premise network, while simultaneously passing both the downstream and upstream CATV signals traveling on the CATV network into and out of the subscriber premise network. In addition, it is desirable for this electronic filter to be of a size small enough to fit in existing CATV network distribution equipment so that existing equipment can be used instead of replacing and/or upgrading the existing hardware.

### DISCLOSURE OF THE INVENTION

This disclosure relates generally to community access or cable television (CATV) signals and to in-home entertainment signals sharing a CATV distribution network. More particularly, the present disclosure relates to a low-pass filter for blocking in-home entertainment signals that are using the CATV distribution network from leaving a subscriber premises network.

A low-pass filter is disclosed which includes an LC resonant circuit element and a first mechanical resonant circuit element electrically coupled to the LC resonant circuit element. In some embodiments the LC resonant circuit element is connected in series with the first mechanical resonant circuit element. In some embodiments the low-pass filter includes a second mechanical resonant circuit element. In some embodiments the LC resonant circuit element is connected in series between the first mechanical resonant circuit element and the second mechanical resonant circuit element. In some embodiments the first mechanical resonant circuit element is a ceramic low-pass filter circuit element. In some embodiments the LC resonant circuit element is an elliptic filter LC resonant circuit element. In some embodiment the LC resonant circuit element is a 9th-order LC resonant filter circuit element.

A low-pass filter circuit is disclosed which includes one or more than one LC resonant circuit element, and one or more than one mechanical resonant circuit element. The low-pass filter circuit passes CATV signals with an attenuation less than −2.5 dB, and passes in-home entertainment signals with an attenuation greater than −70 dB. In some embodiments the CATV signals have a frequency less than or equal to 1002 megahertz (MHz). In some embodiments the in-home entertainment signals have a frequency greater than or equal to 1125 MHz. In some embodiments the one or more than one LC resonant circuit element includes a 9th-order elliptic Chebychev filter. In some embodiments the one or more than one mechanical resonant circuit element comprises a ceramic low-pass filter element. In some embodiments the one or more than one mechanical resonant circuit element comprises two ceramic low-pass filter elements. In some embodiments the 9th-order elliptic Chebychev filter is connected in series between the two ceramic low-pass filter elements.

A method of filtering signals in a CATV signal distribution system is disclosed which includes the step of restricting signals in an in-home entertainment frequency band from exiting a subscriber network of a CATV signal distribution system. The method of filtering signals in a CATV signal distribution system also includes the step of allowing signals in a CATV upstream signal frequency band to exit the subscriber network of the CATV signal distribution system. The method of filtering signals in a CATV signal distribution system also includes the step of allowing signals in a CATV downstream signal frequency band to enter the subscriber network of the CATV signal distribution system. In some embodiments restricting signals in an in-home entertainment frequency band from exiting a subscriber network of a CATV signal distribution system comprises passing signals in an in-home entertainment frequency band through a low-pass filter, wherein the low-pass filter attenuates the signals in the in-home entertainment frequency band an amount equal to or greater than −70 dB, and wherein the low-pass filter includes at least one mechanical resonant circuit element. In some embodiments the in-home entertainment frequency band comprises signals with a frequency equal to or greater than 1125 megahertz.

In some embodiments allowing signals in a CATV upstream signal frequency band to exit the subscriber network of the CATV signal distribution system comprises passing signals in a CATV upstream signal frequency band through the low-pass filter, wherein the low-pass filter attenuates the signals in the CATV upstream signal frequency band an amount less than or equal to −2.5 dB, and wherein the low-pass filter includes at least one LC resonant circuit element. In some embodiments the upstream signal frequency band comprises frequencies from 5 MHz to 42 MHz.

In some embodiments allowing signals in a CATV downstream signal frequency band to enter the subscriber network of the CATV signal distribution system comprises passing signals in a CATV downstream signal frequency band through the low-pass filter, wherein the low-pass filter attenuates the signals in the CATV downstream signal frequency band an amount less than or equal to −2.5 dB. In some embodiments the downstream signal frequency band comprises frequencies from 54 MHz to 1002 MHz.

The foregoing and other features and advantages of the present invention will be apparent from the following more detailed description of the particular embodiments of the invention, as illustrated in the accompanying drawings.

### BRIEF DESCRIPTION OF THE DRAWINGS

FIG. 1 is a simplified schematic view of a portion of a CATV network.

FIG. 2 is a schematic diagram of low-pass filter circuit 210.

FIG. 3 is a graph of the frequency response of low-pass filter circuit 210 of FIG. 2.

FIG. 4 is a schematic diagram of low-pass filter circuit 220.

FIG. 5 is a graph of the frequency response of low-pass filter circuit 220 of FIG. 4.

FIG. 6 is a schematic diagram of low-pass filter circuit 230.

FIG. 7 is a graph of the frequency response of low-pass filter circuit 230 of FIG. 6.

FIG. 8 is a schematic diagram of low-pass filter circuit 56 according to the invention.

FIG. 9 is a graph of the frequency response of low-pass filter circuit 56 of FIG. 8.

FIG. 10 shows method 300 of filtering signals in a community access television signal distribution system.

### DETAILED DESCRIPTION OF EMBODIMENTS OF THE INVENTION

As discussed above, embodiments of the present invention relate to community access or cable television (CATV) signals and to in-home entertainment signals sharing a CATV distribution network. More particularly, the present disclosure relates to a low-pass filter for blocking in-home entertainment signals that are using the CATV distribution network from leaving a subscriber premises network.

CATV networks use an infrastructure of interconnected coaxial cables, splitters, amplifiers, filters, trunk lines, cable taps, drop lines and other signal-conducting devices to supply and distribute high frequency “downstream” signals from a main signal distribution facility, known as a head-end, toward subscriber premises such as homes and businesses. The downstream signals operate the subscriber equipment, such as television sets, telephones, and computers. The typical CATV network is a two-way communication system. CATV networks also transmit “upstream” signals from the subscriber equipment back to the head-end of the CATV network. For example, upstream bandwidth may include data related to video on demand services, such as video requests and billing authorization. Two-way communication is also utilized when using a personal computer connected through the CATV infrastructure to the public Internet, for example when sharing photo albums or entering user account information. In yet another example, voice over Internet protocol (VOIP) telephones and security monitoring equipment use the CATV infrastructure and the public Internet as the communication medium for passing two-way telephone conversations and monitoring functions.

To permit simultaneous communication of upstream and downstream CATV signals and the interoperability of the subscriber equipment and the equipment associated with the CATV network infrastructure outside of subscriber premises, the downstream and upstream signals are confined to two different frequency bands. In most CATV networks the downstream frequency band, or downstream bandwidth, is within the range of 54-1002 megahertz (MHz) and the upstream frequency band, or upstream bandwidth, is within the range of 5-42 MHz.

The downstream signals are delivered from the CATV network infrastructure to the subscriber premises at a CATV entry adapter, which is also commonly referred to as an entry device, terminal adapter or a drop amplifier. The entry adapter is a multi-port device which connects at a subscriber premises entry port to a CATV drop cable from the CATV network infrastructure. The entry adapter connects at a multiplicity of other distribution ports to coaxial cables which extend throughout the subscriber premises to a cable outlet. Each cable outlet is available to be connected to subscriber equipment. Typically, most homes have coaxial cables extending to cable outlets in almost every room, because different types of subscriber equipment may be used in different rooms. For example, television sets, computers and telephone sets are commonly used in many different rooms of a home or office. The multiple distribution ports of the entry adapter deliver the downstream signals to each cable outlet and conduct the upstream signals from the subscriber equipment through the entry adapter to the drop cable and the CATV infrastructure.

In addition to television sets, computers and telephones, a relatively large number of other entertainment and multimedia devices are available for use in homes. For example, a digital video recorder (DVR) is used to record broadcast programming, still photography and moving pictures in a memory medium so that the content can be replayed on a display or television set at a later time selected by the user. As another example, computer games are also played at displays or on television sets. Such computer games may be those obtained over the Internet from the CATV network or from media played on play-back devices connected to displays or television sets. In another example, receivers of satellite-broadcast signals may be distributed for viewing or listening throughout the home. These types of devices, including the more-conventional television sets, telephone sets and devices connected to the Internet by the CATV network are generically referred to as multimedia devices.

An in-home entertainment network may be coupled to the CATV network via the same coaxial cable delivering the downstream and upstream bandwidth of the CATV system. The in-home entertainment network can be a network providing multiple streams of high definition video and gaming entertainment. Examples of in-home entertainment network technologies include Ethernet, HomePlug, HPNA, and 802.11n. In another example, the in-home entertainment network may employ technology standards developed by the Multimedia over Coax Alliance (MoCA). MoCA has developed specifications for products to create an in-home entertainment network for interconnecting presently-known and future multimedia devices, such as set top boxes, routers and gateways, bridges, optical network terminals, computers, gaming systems, display devices, printers, network-attached storage, and home automation such as furnace settings and lighting control.

A MoCA network uses the in-home coaxial cable infrastructure originally established for distribution of CATV signals within the subscriber premises, principally because that coaxial cable infrastructure already exists in most homes and is capable of carrying much more information than is carried in the CATV frequency bands. A MoCA network is established by connecting MoCA-enabled or MoCA interface devices at the cable outlets in the rooms of the subscriber premises. These MoCA interface devices implement a MoCA communication protocol which encapsulates the signals normally used by the multimedia devices within MoCA signal packets and then communicates the MoCA signal packets between other MoCA interfaces devices connected at other cable outlets. The receiving MoCA interface device removes the encapsulated multimedia signals from the MoCA signal packets, and delivers the multimedia signals to the connected display, computer or other multimedia device from which the content is presented to the user.

Each MoCA-enabled device is capable of communicating with every other MoCA-enabled device in the in-home or subscriber premises MoCA network to deliver the multimedia content throughout the home or subscriber premises. The multimedia content that is available from one multimedia device can be displayed, played or otherwise used at a different location within the home, without having to physically relocate the originating multimedia device from one location to another within the subscriber premises. The communication of multimedia content is considered beneficial in more fully utilizing the multimedia devices present in modem homes.

Since the operation of the subscriber premises MoCA network must occur simultaneously with the operation of the CATV services, the MoCA signals utilize a frequency range different from the frequency ranges of the CATV upstream and downstream signals. The typical MoCA frequency band is 1125-1525 MHz. This so-called D band of MoCA signals is divided into eight different frequency ranges, D1-D8, and these eight different D frequency ranges are used to assure communication between the selected MoCA-enabled devices. For example, the D-1 band at 1125-1175 MHz may be used to communicate CATV television programming content between a MoCA interface device associated with a set-top box in a main room of the house and another MoCA interface device connected to a television set in bedroom of the house, while a MoCA interface device connected to a computer gaming multimedia device in a basement room of the house simultaneously communicates computer game content over the D-6 band at 1375-1425 MHz to another MoCA interface device associated with a computer located in a recreation room of the house. The MoCA frequency band also includes other frequency ranges, but the D band is of major relevance because of its principal use in establishing connections between the MoCA interface devices.

Although using the in-home cable infrastructure as the communication medium substantially simplifies the implementation of the MoCA network, there are certain difficulties associated with doing so. One noted issue is that it is undesirable for the in-home entertainment signals generated within a particular subscriber premises to leave the subscriber premises using the CATV network cables. Subscribers do not want to be receiving a neighbor's in-home entertainment signals or sending to a neighbor their own in-home entertainment signals. It is also undesirable for in-home entertainment signals to travel upstream to the CATV head-end facility. It is desirable, therefore, to restrict in-home entertainment signals from leaving the subscriber premises where they were generated. Since the in-home entertainment signals have a different frequency than the CATV signals, a low-pass filter can be used at the subscriber premises entry port to block the exit of in-home entertainment signals, while allowing CATV signals to both enter and exit the subscriber premise network. In a particular example, it is desirable to use a low-pass filter at the subscriber entry port that passes upstream and downstream CATV signals with an attenuation of less than −2.5 dB. In this same example, it is desirable to use the same low-pass filter to block the exit of in-home entertainment signals, by attenuating the in-home entertainment signals an amount equal to −70 dB or greater. It is also desirable for the low-pass filter to be small enough to fit in existing CATV hardware, so that it is not necessary to replace the existing CATV hardware when adding the low-pass filter.

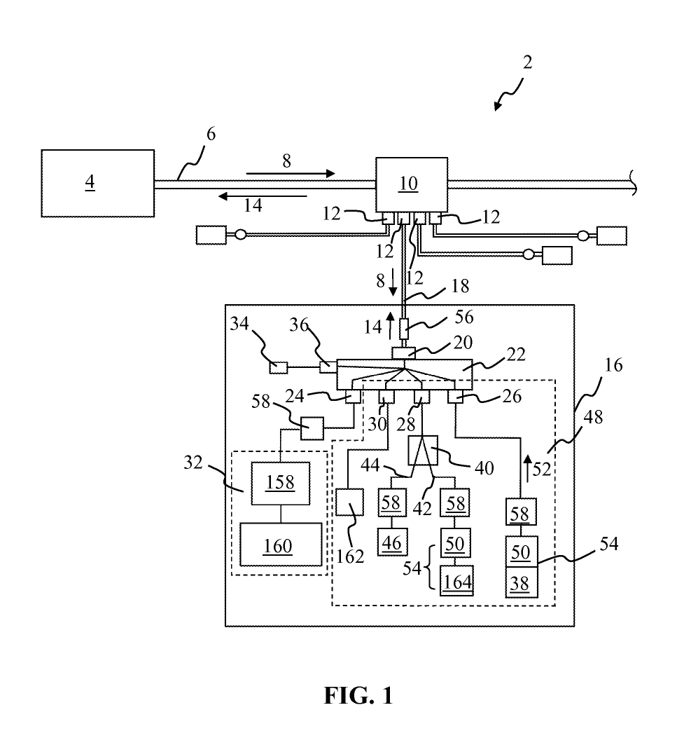

Referring to FIG. 1, a simplified schematic view of a portion of a community access television or cable television (CATV) network 2 includes a head-end facility 4 for processing and distributing signals over the network. Head-end facility 4 is typically controlled by a system operator and includes electronic equipment to receive and re-transmit video and other signals over the local cable infrastructure. One or more main distribution lines 6 carry downstream signals 8 from the head-end facility 4 to a cable tap 10 configured to serve a local distribution network of about 100 to 500 end users, customers, or subscribers. The cable tap 10 includes a plurality of tap ports 12 configured to carry the downstream signals 8 and upstream signals 14 to each subscriber premises 16 via a drop cable 18, which may be a single coaxial cable. In one embodiment, the upstream signals 14 are in the range of 5-42 MHz and the downstream signals 8 are in the range of 54-1002 MHz.

The drop cable 18 enters subscriber premises 16 and passes through low-pass filter 56 according to the invention, which will be described shortly. Low-pass filter 56 allows downstream signals 8 and upstream signals 14 to pass into and out of subscriber premises 16, while restricting subscriber in-home entertainment signals 52 from exiting subscriber premises 16, as explained below. Drop cable 18 connects to splitter 22 having a single CATV network connection or entry port 20 and two or more outlet ports. In this example low-pass filter 56 is positioned along drop cable 18 before splitter 22. It is to be understood that low-pass filter 56 can be placed in other locations, such as inside the housing of splitter 22 or at tap port 12. Low-pass filter 56 can be positioned in any location where it accomplishes the goal of allowing CATV upstream and downstream signals to pass, while restricting in-home entertainment signals from exiting the subscriber network.

In the disclosed example, the splitter is a 4-way CATV entry adapter 22 that includes four outlet ports 24, 26, 28, and 30, respectively. Downstream signals 8 received through entry port 20 are delivered to outlet ports 24, 26, 28, and 30. Downstream signals 8, in this example, are delivered to a passive subscriber device 32, which in this example is an embedded multimedia terminal adapter (eMTA). An eMTA device combines a high-speed data cable modem 158 with voice-over-Internet Protocol technology to create a platform that connects analog telephone 160 and terminal equipment (e.g., fax) to the cable operator's advanced Internet protocol communications network. The cable modem provides a data interface for communicating Internet protocol packets to and from the CATV network 2, and an analog telephone adapter provides a voice over Internet protocol (VoIP) interface for the analog telephone set 160. The eMTA device converts between analog voice signals and packets. A lifeline telephone is a well known example of an eMTA device. It is to be understood that passive subscriber device 32 can be any type of passive subscriber multimedia device.

In the disclosed example, outlet port 26 conducts and receives CATV downstream signals 8 and upstream signals 14 to and from a home-network-enabled subscriber device 38, which in this example is MoCA-enabled set top box (STB) 38. Outlet port 28 conducts downstream signals 8 to a conventional splitter 40. The downstream signals 8 are divided and distributed down first branch 42 to home-network-enabled subscriber device 164, which in this example is MoCA-enabled digital video recorder (DVR) 164. A second branch 44 of splitter 40 distributes downstream CATV signals 8 to a conventional subscriber device 46, which in this example is television set 46. Subscriber device 46 is not home-network-enabled, meaning it is not equipped to process home network signals, such as MoCA signals. Upstream CATV signals 14 sent from the home network-enabled subscriber device DVR 164 and conventional subscriber device television 46 (if any) are combined in splitter 40 and delivered out entry port 20 to main distribution line 6. Outlet port 30 distributes downstream CATV signals 8 to conventional subscriber device 162, which in this embodiment is cable modem 162. It is to be understood that the particular components and interconnections of the example subscriber premise 16 CATV network shown in FIG. 1 is an example only. Components can be added or subtracted from this example, and many other interconnect schemes are possible. Devices 32, 162, 46, 164, and 38 shown in this example can be any type of subscriber multimedia devices.

Subscriber premises 16 includes in-home entertainment network 48 which, in the disclosed embodiment, is a MoCA network. As used herein, an in-home entertainment network carries data on existing coaxial cable infrastructure at a spectrum of frequencies or bandwidth separate from the CATV bandwidth. In that regard, the data is not limited to entertainment, and may include security information, personal information, and the like. MoCA network 48 interconnects MoCA-enabled subscriber devices such as digital video recorders, computers, data modems, computer game playing devices, television sets, television set-top boxes, and other audio and visual entertainment devices.

For example, in-home entertainment signals 52, such as MoCA signals, generated by home network interface device 50 at set top box (STB) 38 travel upstream through outlet port 26 of entry adapter 22, traverse to outlet port 28, travel downstream to splitter 40, and continue to home network interface device 50 associated with MoCA-enabled digital video recorder (DVR) 164. The MoCA interface device 50 associated with DVR 164 extracts the original output signals that were encapsulated or otherwise embodied in the MoCA signals and supplies those original output signals to DVR 164. In this manner, MoCA signals or multimedia content from one multimedia device are communicated through MoCA network 48 to other multimedia devices for use at its location. In terms of the conventional terminology used in the field of networks, the MoCA interface device 50 and the multimedia device 38 and/or 164 form one node 54 of MoCA network 48. MoCA signals are therefore communicated between different MoCA nodes 54 of MoCA network 48. Home network interface device 50 may serve as a hub, or the hub may be integrated within entry adapter 22.

In this example a home network conditioning device 58 is implemented in network 48. When home network conditioning device 58 is coupled with a coaxial device such as the distribution port of a splitter or entry adapter, home network conditioning device 58 conditions in-home entertainment signals 52 to counteract the inherent losses and non-flat frequency response of coaxial cable used to transmit in-home entertainment signals 52. In some examples of CATV network 2 and in-home entertainment network 48, home network conditioning device 58 is not used. In one embodiment home network conditioning device 58 is as described in United States Provisional Patent Application to Erdogan, et al, Ser. No. 61/378, 131 entitled “Home Network Frequency Conditioning Device and Method”.

It is to be understood that CATV network 2 shown in FIG. 1 is one example of a CATV network and in-home entertainment network 48. Other CATV networks and in-home entertainment networks can include other devices and other combinations of devices.

As discussed earlier, in order to prevent in-home entertainment network signals 52 from passing upstream to main distribution line 6, low-pass filter 56 is integrated within entry adapter 22 or upstream thereof. Low-pass filter 56 passes downstream and upstream CATV signals 8 and 14, but attenuates in-home entertainment network bandwidth, such as MoCA signals 52. Thus, low-pass filter 56 effectively prohibits in-home entertainment network signals 52 from exiting in-home entertainment network 48.

In a particular example it is desirable for low-pass filter 56 to pass CATV upstream signals 14 and CATV downstream signals 8 with an attenuation of less than −2.5 dB. Signal attenuation means signal diminishment or extinction, and is the opposite of signal amplification. Signal attenuation is measured in decibels (dB), and in particular, signal attenuation is measured in a negative number of dB since signal attenuation instead of signal amplification is occurring. A smaller or lower amount of signal attenuation means a smaller negative number of dB of attenuation. A greater or larger amount of attenuation means a larger negative number of dB of attenuation.

For low-pass filter 56 to pass upstream and downstream CATV signals with an attenuation of less than −2.5 dB means the amount of dB of attenuation can vary from 0 dB to −2.5 dB. In this example the filter pass-band—the frequency band within which signals are passed—is from 0 MHZ to 1002 MHz, encompassing both downstream signal 8 and upstream signal 14. A positive number of attenuation would indicate signal amplification. In this case signal amplification of the upstream or downstream CATV signals 14 and 8 is not specifically prohibited but is unlikely and not specifically desired. This example of −2.5 dB or less of signal attenuation for upstream and downstream CATV signals 8 and 14 is used throughout this document, but it is to be understood that low-pass filter 56 is not limited in this regard. Some applications require different levels of attenuation, greater or lesser, of upstream and downstream CATV signals 14 and 8 that are passed through (transmitted through) low-pass filter 56. In some embodiments of low-pass filter 56 the pass-band includes other frequency ranges and/or limits.

In this same example it is desirable for low-pass filter 56 to block or prohibit in-home entertainment signals 52 from exiting in-home entertainment network 48. Blocking signals, rejecting signals, restricting signals, or prohibiting signals from exiting means to pass signals through a filter which attenuates or extinguishes the signal amplitude to a large degree. In this example it is desirable for low-pass filter 56 to block in-home entertainment signals 52 with an attenuation of −70 dB or greater. For low-pass filter 56 to block in-home entertainment signals with an attenuation of −70 dB or greater means the amount of attenuation can vary from a level of −70 dB to larger negative numbers. In this example the stop-band—the frequency band within which signals are blocked or restricted—is 1125 MHz and higher. This example of −70 dB or greater of signal attenuation for in-home entertainment signals 52 is used throughout this document, but it is to be understood that low-pass filter 56 is not limited in this regard. Some applications require different levels of attenuation, greater or lesser, for in-home entertainment signals 52 that are passed through low-pass filter 56.

As discussed earlier, it is also desirable for low-pass filter 56 to have a physical size small enough to fit in existing CATV network equipment. In some embodiments low-pass filter 56 is integrated into splitter 22, for example but not by way of limitation. In some embodiments low-pass filter 56 is integrated into other CATV network equipment. In some embodiments low-pass filter 56 is a stand-alone device.

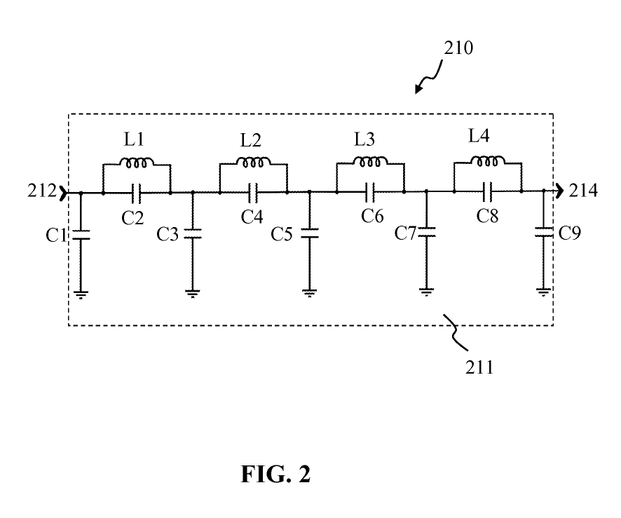

FIG. 2 through FIG. 7 shows examples of traditional low-pass filters and their frequency response, and the reasons why they are unsuitable for this application.

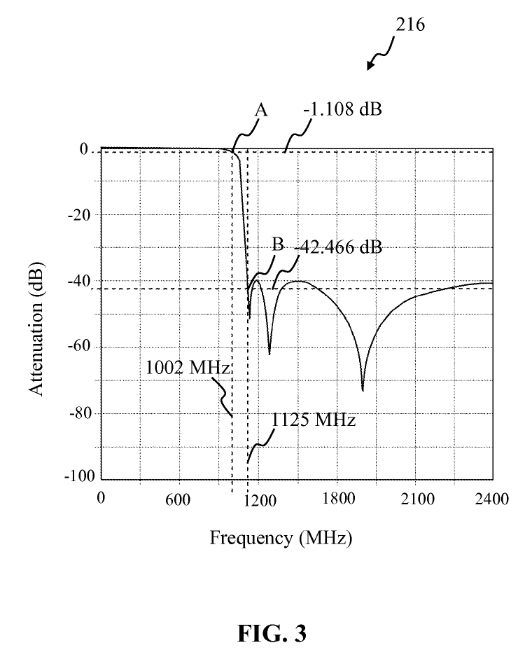

FIG. 2 is a schematic diagram of low-pass filter 210 which includes LC resonant circuit element 211. Signals enter low-pass filter 210 at entry port 212 and exit low-pass filter 210 at exit port 214. Low pass-filter 210 is a 9th-order Chebychev elliptic low-pass filter. LC resonant circuit element 211 includes C1 through C9 and L1 through L4. An LC resonant circuit element is a resonant filter circuit which includes at least one inductor and at least one capacitor. Frequency response 216 shown in FIG. 3 shows the frequency response of low-pass filter 210. In our example the goal is for the attenuation of frequencies leas than or equal to 1002 MHZ to be less than −2.5 dB, and for the attenuation at frequencies greater than or equal to 1125 MHz to be greater than −70 dB. Point A indicates the response of low-pass filter 210 at 1002 MHz, which for low-pass filter 210 is −1.108 dB. Point B indicates the response of low-pass filter 210 at 1125 MHz, which is −42.466 dB. Thus, the stop-band attenuation of filter 210 is not providing enough attenuation for our application, at −42.66 dB instead of greater than or equal to −70 dB.

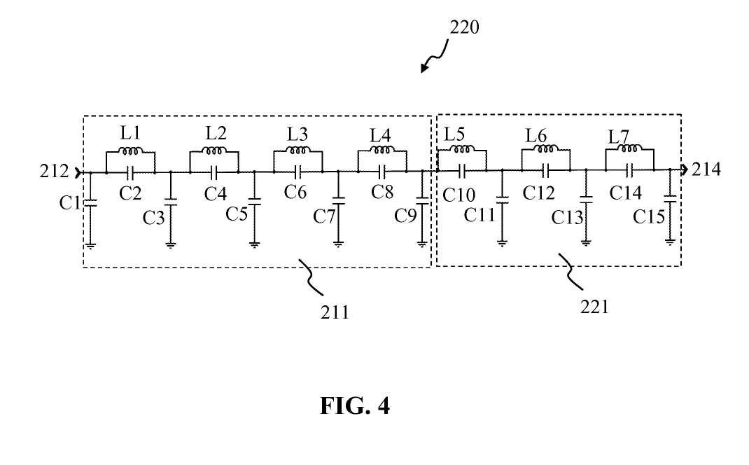

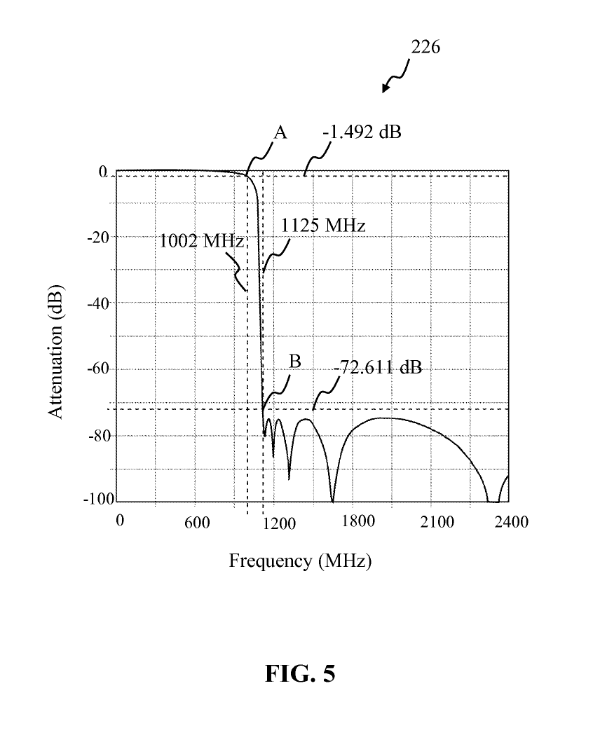

One possible way to increase the stop-band rejection (stop-band response) of low-pass filter 210 is to add more LC resonant circuit elements. FIG. 4 shows a schematic diagram of low-pass filter 220. Low-pass filter 220 in FIG. 4 has added LC resonant circuit element 221, with LC resonant circuit element 221 including C10 through C15, and L5 through L7. The frequency response 226 of low-pass filter 220 is shown in FIG. 5. FIG. 5 shows that low-pass filter 220 has desirable pass-band response and desirable stop-band response, with a frequency response at 1002 MHz of −1.492 dB, and a frequency response at 1125 MHz of −72.611 dB. The problem with using filter 220 in a CATV application is that inductors and capacitors tend to be large and bulky. Using low-pass filter 220 in a CATV piece of equipment such as a splitter or a port would require the piece of equipment to be enlarged as compared to the size currently in use as existing CATV equipment. It is desirable to have a low-pass filter that both possesses the desired frequency response and that fits in existing CATV hardware.

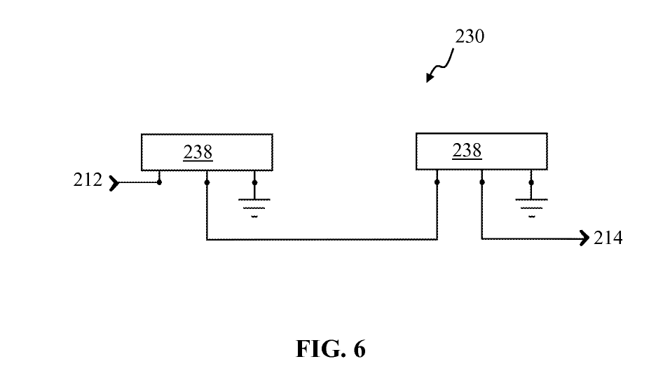

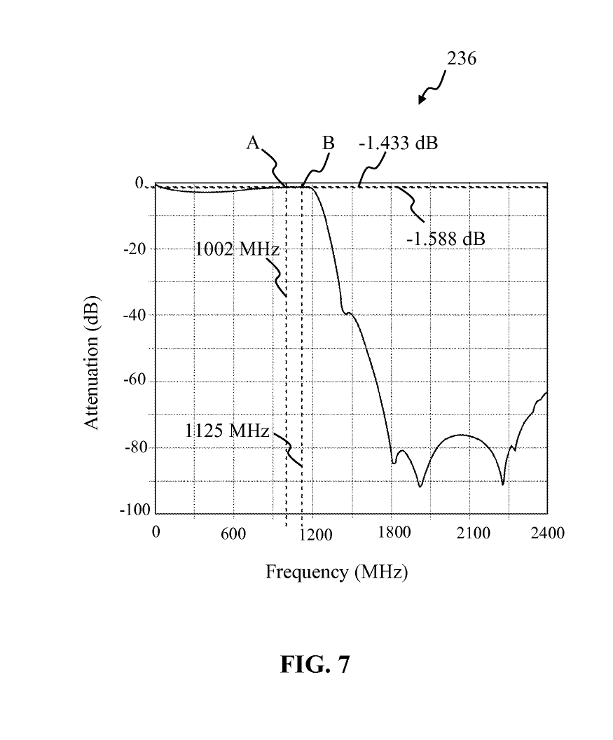

FIG. 6 shows a schematic diagram of low-pass filter 230, and FIG. 7 shows frequency response 236 of low-pass filter 230. Low-pass filter circuit 230 includes two mechanical resonant circuit elements 238. A mechanical resonant circuit element is a circuit that includes at least one mechanical resonator. A mechanical resonator is a device that mechanically resonates and that is or can be used in an electric circuit, such as quartz, ceramics, piezoelectric materials, or the like. Low-pass filter 230 is unsuitable for our application because it has poor selectivity—low quality or Q response. Low-pass filter 230 has acceptable pass-band response, with an attenuation of frequencies less than 1002 MHz less than −3 or −4 dB, and an attenuation at 1002 MHz of −1.588 dB. And low-pass filter 230 has a stop-band response of greater than −70 dB, but it has poor selectivity—or low quality or Q response. The attenuation at 1002 MHz is −1.588 dB, which is acceptable for our application. The attenuation falls off slowly at frequencies higher than 1002 MHz, however. At 1125 MHz the attenuation has changed slightly to −1.433 dB, after which the response falls off slowly, not reaching a level of attenuation greater than −70 dB until between 1700 and 1800 MHz. This response is not acceptable for this CATV application. Low-pass filter 230, if used in our application, would not attenuate frequencies above 1125 MHz enough, allowing these frequencies to exit subscriber premise 16.

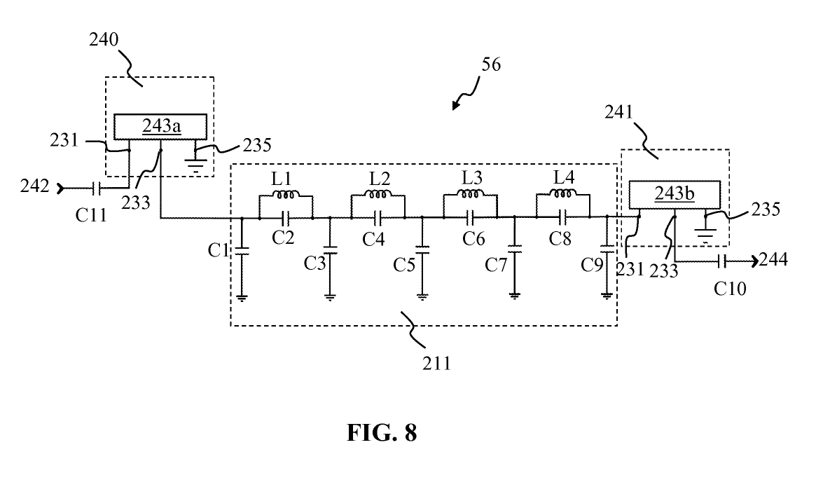

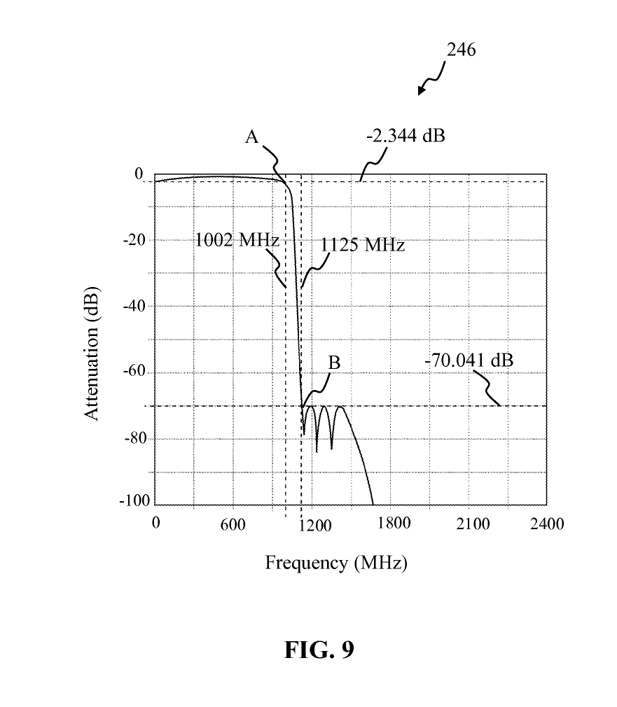

FIG. 8 shows a schematic diagram of one embodiment of low-pass filter 56 according to the invention. FIG. 9 shows the frequency response 246 of low-pass filter 56 of FIG. 8. Low-pass filter 56 according to the invention includes one or more than one LC resonant circuit element and one or more than one mechanical resonant circuit element. Low-pass filter 56 of FIG. 8 includes LC resonant circuit element 211. In this embodiment LC resonant circuit element 211 includes nine capacitors, C1 through C9, and four inductors, L1 through L9. The number of capacitors and inductors in the LC resonant circuit element of low-pass filter circuit 56 can vary. In some embodiments the LC resonant circuit element of low-pass filter circuit 56 includes one capacitor and one inductor. In some embodiments the LC resonant circuit element of low-pass filter circuit 56 includes other numbers of capacitors and inductors, according to the specific frequency response desired. In some embodiments of low-pass filter circuit 56, more than one LC resonant circuit element is included, where each LC resonant circuit element includes at least one inductor and at least one capacitor. Low-pass filter circuit 56 according to the invention includes at least one LC resonant circuit element, where each LC resonant circuit element includes at least one inductor and at least one capacitor.

Low-pass filter circuit 56 according to the invention of FIG. 8 includes two mechanical resonant circuit elements 240 and 241. In this embodiment each mechanical resonant circuit element 240 and 241 is a ceramic low-pass filter 243. Each ceramic low-pass filter element 243a and 243b includes an input node 231, an output node 233, and a ground node 235. Low-pass filter circuit 56 includes signal input port 242, which is coupled to input node 231 of first ceramic low-pass filter 243a through input capacitor C11. Output node 233 of first ceramic low-pass filter circuit 243a is coupled to capacitor C1 of LC resonant circuit element 211. Each ground node 235 of ceramic low-pass filters 243a and 243b is coupled to a current return path. Capacitor C9 is coupled to input node 231 of second ceramic low-pass filter 243b. Output node 233 of second ceramic low-pass filter 243b is coupled to low-pass filter circuit 56 output node 244 through output capacitor C10. In this embodiment signals passing through low-pass filter circuit 56 enter input port 242, pass through first ceramic low-pass filter 243a, then pass through LC resonant circuit element 211, and then through second ceramic low-pass filter 243b, exiting low-pass filter circuit 56 at output port 244. In this embodiment of low-pass filter 56 according to the invention, first mechanical resonant circuit element 240 is connected in series to LC resonant circuit element 211. In this embodiment of low-pass filter 56 according to the invention, LC resonant circuit element 211 is connected in series with second mechanical resonant circuit element 241. In this embodiment of low-pass filter 56 according to the invention, LC resonant circuit element 211 is connected in series between first mechanical resonant circuit element 240 and second mechanical resonant circuit element 241. In low-pass filter circuit 56 according to the invention, LC resonant circuit element 211 and mechanical resonant circuit elements 240 and 241 can be connected in many different ways, including but not limited to, in series, in parallel, or in any combination of series or parallel connections.

In the embodiment of low-pass filter circuit 56 shown in FIG. 8, LC resonant circuit element 211 is an elliptic low-pass filter circuit, with equalized ripple in the stop-band and the pass-band. In some embodiments of low-pass filter circuit 56, LC resonant circuit element 211 is a low-pass filter of a type different from an elliptic filter. In the embodiment of low-pass filter circuit 56 shown in FIG. 8, LC resonant circuit element 211 is a 9th-order elliptic Chebychev low-pass filter circuit, connected in series between the pair of mechanical resonant circuit elements 240 and 241, where mechanical resonant circuit elements 240 and 241 are each a ceramic low-pass filter circuit element 243. In some embodiments of low-pass filter circuit 56, LC resonant circuit element 211 is a low-pass Chebychev filter with a number of orders other than 9. In some embodiments of low-pass filter circuit 56, LC resonant circuit element 211 is a low-pass Chebychev filter of a type different from an elliptic filter. In some embodiments of low-pass filter circuit 56, LC resonant circuit element 211 is a Butterworth low-pass filter . In some embodiments of low-pass filter circuit 56, LC resonant circuit element 211 is a low-pass filter of a type different from a Chebychev or Butterworth filter circuit. In low-pass filter circuit 56 according to the invention, LC resonant circuit element 211 can be any type of LC resonant circuit, with any number of elements and many different types of circuit elements.

The embodiment of low-pass filter 56 according to the invention of FIG. 8 includes one LC resonant circuit element 211. In some embodiments low-pass filter 56 according to the invention includes more than one LC resonant circuit element, where each LC resonant circuit element includes at least one capacitor and at least one inductor. Each LC resonant circuit element includes one or more than one inductor and one or more than one capacitor. In some embodiments the one or more than one LC resonant circuit element of low-pass filter circuit 56 includes additional elements that are not inductors or capacitors. In those embodiments of low-pass filter 56 where there are more than one LC resonant circuit element, the LC resonant circuit elements can be connected in series, in parallel, in any combination of series or parallel, or in other arrangements

The embodiment of low-pass filter 56 according to the invention of FIG. 8 includes a first and a second mechanical resonant circuit element 240 and 241. In some embodiments low-pass filter 56 according to the invention includes only one mechanical resonant circuit element. In some embodiment low-pass filter 56 according to the invention includes more than two mechanical resonant circuit elements. In the embodiment of low-pass filter circuit 56 of FIG. 8, mechanical resonant circuit element 240 and 241 are each a ceramic low-pass filter 243. In some embodiments of low-pass filter circuit 56, mechanical resonant circuit element 240 and/or 241 include more than one ceramic low-pass filter 243. In some embodiments of low-pass filter circuit 56, mechanical resonant circuit element 240 and/or 241 includes other mechanically resonant elements. In some embodiments of low-pass filter circuit 56, mechanical resonant circuit element 240 and/or 241 includes other electronic components in addition to ceramic low-pass filter 238. In some embodiments of low-pass filter circuit 56, mechanical resonant circuit element 240 and/or 241 includes other electronic components in addition to a mechanical resonant circuit element.

Mechanical resonant circuit elements 240 and 241 can include any type of mechanically resonant circuit element known now or in the future, including but not limited to ceramic elements, piezoelectric elements, quartz elements, silicon elements, zinc-oxide elements, or any other mechanical or electromechanical resonating element. The one or more than one mechanical resonant circuit element included in low-pass filter 56 can be connected to each other or other circuit elements in series, in parallel, in a combination or series or parallel, or in other arrangements.

FIG. 9 shows the frequency response to low-pass filter 56 according to the invention of FIG. 8. The embodiment of low-pass filter 56 of FIG. 8 passes CATV signals with an attenuation of −2.5 dB or less. In the example in this document, CATV signals have a frequency less than or equal to 1002 MHz. Low-pass filter 56 of FIG. 8 passes signals with a frequency less than or equal to 1002 MHz with an attenuation of less than −2.5 MHz, as can be seen in FIG. 9. The attenuation of low-pass filter circuit 56 of FIG. 8 at 1002 MHz is −2.344 MHz, as is shown by point A in FIG. 9. In some embodiments of low-pass filter circuit 56, CATV signals with a frequency band other than 0 MHz to 1002 MHz are passed by low-pass filter circuit 56 with an attenuation less than −2.5 dB. In some embodiments of low-pass filter circuit 56, the attenuation of CATV signals being passed by low-pass filter 56 is a level different from −2.5 dB.

The embodiment of low-pass filter 56 of FIG. 8 rejects in-home entertainment signals with an attenuation of −70 dB or greater, as can be seen in FIG. 9. In this embodiment in-home entertainment signals have frequencies greater than or equal to 1125 MHz . Low-pass filter 56 of FIG. 8 rejects signals with frequencies greater than or equal to 1125 MHz with an attenuation greater than −70 dB, as can be seen in FIG. 9. The attenuation of low-pass filter circuit 56 according to the invention of FIG. 8 at 1125 MHz is −70.041, as can be seen by point B in FIG. 9. Thus low-pass filter has good selectivity, or Q, as seen by the difference in attenuation between point A and point B. In some embodiments of low-pass filter circuit 56, in-home entertainment signals with a frequency band other than 1125 MHz and higher are passed by low-pass filter circuit 56 with an attenuation of −70 dB and greater. In some embodiments of low-pass filter circuit 56, the attenuation of in-home entertainment signals being passed by low-pass filter 56 is a level different from −70 dB.

Low-pass filter circuit 56 not only has the frequency response characteristics that are desired for this CATV application, it is sized small enough to fit in existing CATV equipment. The use of two mechanical resonant circuit elements 240 and 241 improves the stop-band rejection of low-pass filter circuit 56 as compared to low-pass filter 210, without incurring the size penalty of low-pass filter 220.

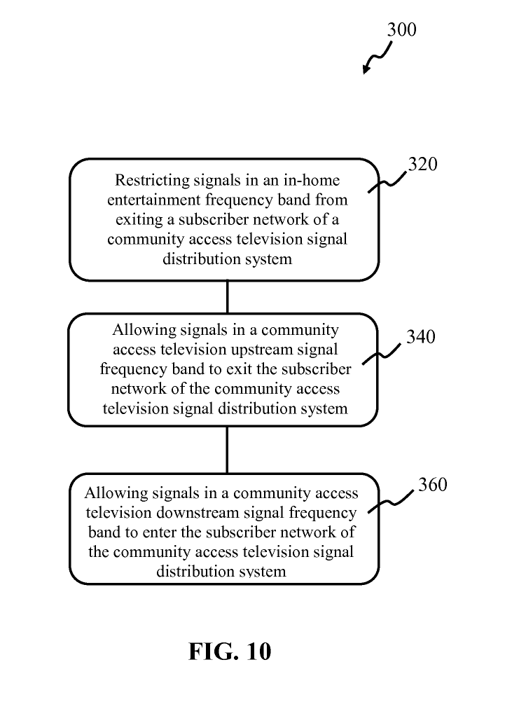

FIG. 10 shows method 300 of filtering signals in a CATV signal distribution system according to the invention. Method 300 of filtering signals in a CATV signal distribution system includes step 320 restricting signals in an in-home entertainment frequency band from exiting a subscriber network of a CATV signal distribution system. Method 300 also includes step 340 allowing signals in a CATV upstream signal frequency band to exit the subscriber network of the CATV signal distribution system, and step 360 allowing signals in a CATV downstream signal frequency band to enter the subscriber network of the CATV signal distribution system. Method 300 can include many other steps.

Step 320 restricting signals in an in-home entertainment frequency band from exiting a subscriber network of a CATV signal distribution system includes any steps take to restrict or suppress the signals in an in-home entertainment system frequency band from exiting the subscriber network. In-home entertainment signals are generated and used within the subscriber network that exists in a particular home and are not meant to be transmitted to the CATV signal distribution system head-end facility or to other subscriber premises or networks. Step 320 can include many steps. In some embodiments step 320 includes passing signals in an in-home entertainment frequency band through a low-pass filter, wherein the low-pass filter attenuates the signals in the in-home entertainment frequency band. In some embodiments step 320 includes passing signals in an in-home entertainment frequency band through a low-pass filter, wherein the low-pass filter attenuates the signals in the in-home entertainment frequency band an amount equal or greater than −70 dB. In some embodiments step 320 includes passing signals in an in-home entertainment frequency band through a low-pass filter, wherein the low-pass filter attenuates the signals in the in-home entertainment frequency band an amount greater than −70 dB. In some embodiments step 320 includes passing signals in an in-home entertainment frequency band through a low-pass filter, wherein the low-pass filter attenuates the signals in the in-home entertainment frequency band an amount less than −70 dB.

In some embodiments step 320 includes passing signals in an in-home entertainment frequency band through a low-pass filter, wherein the low-pass filter attenuates the signals in the in-home entertainment frequency band and wherein the low-pass filter includes at least one mechanical resonant circuit element. In some embodiments the mechanical resonant circuit element is a ceramic low-pass filter circuit element. In some embodiments step 320 includes passing signals in an in-home entertainment frequency band through a low-pass filter, where the low-pass filter attenuates the signals in the in-home entertainment frequency band, and where the low-pass filter includes at least one mechanical resonant circuit element and at least one LC resonant circuit element. In some embodiments step 320 includes passing signals in an in-home entertainment frequency band through a low-pass filter, where the low-pass filter attenuates the signals in the in-home entertainment frequency band by an amount equal to or greater than −70 dB, and where the low-pass filter includes two mechanical resonant circuit elements and one or more than one LC resonant circuit element.

In some embodiments the in-home entertainment frequency band comprises signals with a frequency equal to or greater than 1125 megahertz. In some embodiments the in-home entertainment frequency band comprises signals with a frequency equal to or greater than a frequency other than 1125 megahertz. In some embodiments the at least one mechanical resonant circuit element includes a ceramic low-pass filter circuit element. In some embodiments the at least one LC resonant circuit element includes a Chebychev filter. In some embodiments the at least one LC resonant circuit element includes an elliptic filter. In some embodiments the at least one LC resonant circuit element includes a 9th-order elliptic Chebychev filter.

Step 340 allowing signals in a CATV upstream signal frequency band to exit the subscriber network of the CATV signal distribution system according to the invention includes steps taken to allow upstream signals that are generated within the subscriber network and headed to the CATV head-end facility to exit the subscriber network. Step 340 can include many steps. In some embodiments step 340 allowing signals in a CATV upstream signal frequency band to exit the subscriber network of the CATV signal distribution system includes passing signals in a CATV upstream signal frequency band through the low-pass filter, wherein the low-pass filter attenuates the signals in the CATV upstream signal frequency band an amount less than or equal to −2.5 dB. In some embodiments step 340 allowing signals in a CATV upstream signal frequency band to exit the subscriber network of the CATV signal distribution system includes passing signals in a CATV upstream signal frequency band through the low-pass filter, where the low-pass filter attenuates the signals in the CATV upstream signal frequency band an amount equal to an attenuation value other than −2.5 dB.

In some embodiments step 340 allowing signals in a CATV upstream signal frequency band to exit the subscriber network of the CATV signal distribution system includes passing signals in a CATV upstream signal frequency band through the low-pass filter, where the low-pass filter attenuates the signals in the CATV upstream signal frequency band an amount less than or equal to −2.5 dB, and where the low-pass filter includes at least one LC resonant circuit element. In some embodiments step 340 allowing signals in a CATV upstream signal frequency band to exit the subscriber network of the CATV signal distribution system includes passing signals in a CATV upstream signal frequency band through the low-pass filter, where the low-pass filter attenuates the signals in the CATV upstream signal frequency band an amount less than or equal to −2.5 dB, and wherein the low-pass filter includes at least one LC resonant circuit element and at least one mechanical resonant circuit element. In some embodiments the at least one mechanical resonant circuit element includes a ceramic low-pass filter circuit element. In some embodiments the at least one LC resonant circuit element includes a Chebychev filter. In some embodiments the at least one LC resonant circuit element includes an elliptic filter. In some embodiments the at least one LC resonant circuit element includes a 9th-order elliptic Chebychev filter. In some embodiments the CATV upstream signal frequency band includes signals with frequencies in the 5 MHz to 42 MHz frequency band. In some embodiments the CATV upstream signal frequency band includes signals with frequencies outside the 5-42 MHz frequency band.

Step 360 allowing signals in a CATV downstream signal frequency band to enter the subscriber network of the CATV signal distribution system according to the invention includes steps taken to allow downstream signals that are generated within the CATV head-end facility and headed to the subscriber network, to enter the subscriber network. Step 360 can include many steps. In some embodiments step 360 allowing signals in a CATV downstream signal frequency band to enter the subscriber network of the CATV signal distribution system includes passing signals in a CATV downstream signal frequency band through the low-pass filter, where the low-pass filter attenuates the signals in the CATV downstream signal frequency band an amount less than or equal to −2.5 dB. In some embodiments step 360 allowing signals in a CATV downstream signal frequency band to enter the subscriber network of the CATV signal distribution system includes passing signals in a CATV downstream signal frequency band through the low-pass filter, wherein the low-pass filter attenuates the signals in the CATV downstream signal frequency band an amount equal to an attenuation value other than −2.5 dB.

In some embodiments step 360 allowing signals in a CATV downstream signal frequency band to enter the subscriber network of the CATV signal distribution system includes passing signals in a CATV downstream signal frequency band through the low-pass filter, wherein the low-pass filter attenuates the signals in the CATV downstream signal frequency band an amount less than or equal to −2.5 dB, and where the low-pass filter includes at least one LC resonant circuit element. In some embodiments step 360 allowing signals in a CATV downstream signal frequency band to enter the subscriber network of the CATV signal distribution system includes passing signals in a CATV downstream signal frequency band through the low-pass filter, where the low-pass filter includes at least one LC resonant circuit element. In some embodiments step 360 allowing signals in a CATV downstream signal frequency band to enter the subscriber network of the CATV signal distribution system includes passing signals in a CATV downstream signal frequency band through the low-pass filter, where the low-pass filter includes at least one LC resonant circuit element and at least one mechanical resonant circuit element. In some embodiments step 360 allowing signals in a CATV downstream signal frequency band to enter the subscriber network of the CATV signal distribution system includes passing signals in a CATV downstream signal frequency band through the low-pass filter, where the low-pass filter attenuates the signals in the CATV downstream signal frequency band an amount less than or equal to −2.5 dB, and where the low-pass filter includes at least one LC resonant circuit element and at least one mechanical resonant circuit element. In some embodiments the at least one mechanical resonant circuit element includes a ceramic low-pass filter circuit element. In some embodiments the at least one LC resonant circuit element includes a Chebychev filter. In some embodiments the at least one LC resonant circuit element includes an elliptic filter. In some embodiments the at least one LC resonant circuit element includes a 9th-order elliptic Chebychev filter. In some embodiments the community access television downstream signal frequency band includes signals with frequencies in the 54 MHz to 1002 MHz frequency band. In some embodiments the community access television downstream signal frequency band includes signals with frequencies outside the 54-1002 MHz frequency band.

It has been shown that low-pass filter circuit 56 according to the invention can be placed at the entry port of a subscriber network in a CATV signal distribution system, and the low-pass filter can restrict in-home entertainment signals from exiting the subscriber network In a particular embodiment, low-pass filter 56 attenuates the in-home entertainment signals passing through low-pass filter circuit 56 by an amount equal to or greater than −70 dB. Low-pass filter circuit 56 allows CATV signals in both the upstream frequency band and the downstream frequency band to pass through low-pass filter 56 into and out of the subscriber network. In a particular embodiment the upstream and downstream CATV signals are attenuated less than −2.5 dB when passing through low-pass filter circuit 56. Low-pass filter circuit 56 allows upstream and downstream CATV signal transmission to occur with a minimum of signal attenuation, while strongly attenuating the in-home entertainment signal frequency band exiting the subscriber network. Low-pass filter circuit 56 includes at least one LC resonant circuit element and at least one mechanical resonant circuit element. The use of at least one mechanical resonant circuit element decreases the size of low-pass filter circuit 56 so that it can fit in existing CATV signal distribution equipment. The use of at least one mechanical resonant circuit element provides a high-Q filter with good selectivity between the in-home entertainment signal frequency band and the CATV signal frequencies.

The embodiments and examples set forth herein were presented in order to best explain the present invention and its practical application and to thereby enable those of ordinary skill in the art to make and use the invention. However, those of ordinary skill in the art will recognize that the foregoing description and examples have been presented for the purposes of illustration and example only. The description as set forth is not intended to be exhaustive or to limit the invention to the precise form disclosed. Many modifications and variations are possible in light of the teachings above.

1. A low-pass filter comprising:
an LC resonant circuit element; and
a first mechanical resonant circuit element electrically coupled to the LC resonant circuit element.

2. The circuit of claim 1, wherein the LC resonant circuit element is connected in series with the first mechanical resonant circuit element.

3. The circuit of claim 1, further comprising a second mechanical resonant circuit element.

4. The circuit of claim 3, wherein the LC resonant circuit element is connected in series between the first mechanical resonant circuit element and the second mechanical resonant circuit element.

5. The circuit of claim 1, wherein the first mechanical resonant circuit element is a ceramic low-pass filter circuit element.

6. The circuit of claim 5, wherein the LC resonant circuit element is an elliptic filter LC resonant circuit element.

7. The circuit of claim 5, wherein the LC resonant circuit element is a 9th-order LC resonant filter circuit element.

8. A low-pass filter circuit comprising:
one or more than one LC resonant circuit element; and
one or more than one mechanical resonant filter element;
wherein the low-pass filter circuit passes community access television signals with an attenuation less than −2.5 dB, and
wherein the low-pass filter circuit rejects in-home entertainment signals with an attenuation greater than −70 dB.

9. The filter of claim 8, wherein the community access television signals have a frequency less than or equal to 1002 megahertz.

10. The filter of claim 9, wherein the in-home entertainment signals have a frequency greater than or equal to 1125 megahertz.

11. The filter of claim 10, wherein the one or more than one LC resonant circuit element comprises a 9th-order elliptic Chebychev filter.

12. The filter of claim 11, wherein the one or more than one mechanical resonant filter element comprises a ceramic low-pass filter element.

13. The filter of claim 11, wherein the one or more than one mechanical resonant filter element comprises two ceramic low-pass filter elements.

14. The filter of claim 13, wherein the 9th-order elliptic Chebychev filter is connected in series between the two ceramic low-pass filter elements.

15. A method of filtering signals in a community access television signal distribution system comprising:
restricting signals in an in-home entertainment frequency band from exiting a subscriber network of a community access television signal distribution system;
allowing signals in a community access television upstream signal frequency band to exit the subscriber network of the community access television signal distribution system;
and
allowing signals in a community access television downstream signal frequency band to enter the subscriber network of the community access television signal distribution system.

16. The method of claim 15, wherein restricting signals in an in-home entertainment frequency band from exiting a subscriber network of a community access television signal distribution system comprises passing signals in an in-home entertainment frequency band through a low-pass filter, wherein the low-pass filter attenuates the signals in the in-home entertainment frequency band an amount equal to or greater than −70 dB, and wherein the low-pass filter includes at least one mechanical resonant circuit element.

17. The method of claim 16, wherein allowing signals in a community access television upstream signal frequency band to exit the subscriber network of the community access television signal distribution system comprises passing signals in a community access television upstream signal frequency band through the low-pass filter, wherein the low-pass filter attenuates the signals in the community access television upstream signal frequency band an amount less than or equal to −2.5 dB, and wherein the low-pass filter includes at least one LC resonant circuit element.

18. The method of claim 17, wherein allowing signals in a community access television downstream signal frequency band to enter the subscriber network of the community access television signal distribution system comprises passing signals in a community access television downstream signal frequency band through the low-pass filter, wherein the low-pass filter attenuates the signals in the community access television downstream signal frequency band an amount less than or equal to −2.5 dB.

19. The method of claim 18, wherein the in-home entertainment frequency band comprises signals with a frequency equal to or greater than 1125 megahertz.

20. The method of claim 19, wherein the community access television downstream signal frequency band comprises signals with a frequency less than or equal to 1002 megahertz.
